(19) United States
(12) Patent Application Publication
(10) Pub. No.: US 2015/0162367 A1
(43) Pub. Date: Jun. 11, 2015

(54) SEMICONDUCTOR STRUCTURE FOR SUPPRESSING HOT CLUSTER AND METHOD OF FORMING SEMICONDUCTOR FOR SUPPRESSING HOT CLUSTER

(71) Applicant: Himax Imaging, Inc., Grand Cayman (KY)

(72) Inventors: Kihong Kim, Grand Cayman (KY); Chung-Ren Li, Grand Cayman (KY)

(73) Assignee: Himax Imaging, Inc., Grand Cayman (KY)

(21) Appl. No.: 14/097,272

(22) Filed: Dec. 5, 2013

(51) Int. Cl. H01L 27/146

(52) U.S. Cl. CPC H01L 27/1463; H01L 27/14689

(57) ABSTRACT

A semiconductor structure for suppressing a hot cluster is disclosed. An isolation well region which has an extension tip extending toward a substrate is formed in an epitaxial layer disposed on the substrate are of a first conductive type. A first element region and a second element region are disposed in the epitaxial layer to sandwich the isolation well region. The extension tip and the substrate together suppresses a leak current which forms a hot cluster and flows from the first element region via the extension tip to the second element region.

### BACKGROUND OF THE INVENTION

1. Field of the Invention

The present invention generally relates to a semiconductor structure. In particular, the present invention is directed to a semiconductor structure for suppressing a hot cluster and method of forming a semiconductor structure for suppressing a hot cluster.

2. Description of the Prior Art

A complementary metal-oxide-semiconductor (CMOS) is a versatile electronic component. One of the functions of the CMOS is an imaging pixel to serves as a CMOS image sensor (CIS). As shown in FIG. 1A, due to process variations, some of the imaging pixels 11 become the bad pixel 12, also known as a hot pixel 12. One extremely hot pixel 12 may jeopardize other pixels 13 nearby to form a hot cluster 14. Uncorrected hot pixels 14 in the image sensors may annoy human's eyes that perceive images so reduction of the hot pixels and of hot clusters is an important task of the optimization of CMOS image sensors.

As shown in FIGS. 1A and 1B, a single hot pixel 15 which is scattered in the image array 10 may be corrected through conventional proper signal processing. However, as shown in FIG. 1A, some extremely hot pixels 12 may collaterally damaging neighboring pixels 13 to collectively form an image cluster 14, namely a hot cluster 14. In spite of the signal processing, a single hot pixel 15 may be corrected but a cluster 14 may be beyond the capability of the signal processing so the neighboring pixels 13 are left uncorrected after the signal processing, as shown in FIG. 1B.

As shown in FIG. 1A, any hot pixel 12 is the source of a leak current. The leak current easily travels from the hot pixel 12 to another neighboring good pixel 13 because the hot pixel 12 and the neighboring good pixel 13 are not in absolute electrical isolation. As a result, as shown in FIG. 1A, one extremely hot pixel 12 collaterally damages neighboring pixels 13 to form multiple bad pixels 13 which collectively turn into a hot cluster 14.

These hot pixels, in most cases, are formed during the image sensor fabricating process. For example, the plasma etching which damages the photo diode surface or the shallow trench isolation can generate abnormally high level of electrons leading to extremely hot pixels. Although defining and removing hot pixels is the priority to achieve better image quality, locating the source is never easy.

In this aspect, novel fashions are still needed to keep extremely hot pixels from collaterally damaging the neighboring pixels and from forming a hot cluster. In such a way, a better image quality can be obtained.

### SUMMARY OF THE INVENTION

Given the above, the present invention accordingly proposes novel fashions to suppress extremely hot pixels so they are not able to collaterally damage the neighboring pixels and not able to form a hot cluster. As a result, these extremely hot pixels may be confined as single hot pixels and can be corrected in accordance with the above-mentioned way.

The present invention in a first aspect proposes a method for forming a semiconductor. First, an epitaxial layer is formed on a substrate. Second, a shallow trench is formed in the epitaxial layer. Then, an implantation step is carried out to form an isolation well region in the epitaxial layer to surround the shallow trench after forming the shallow trench. The isolation well region has an extension tip extending toward the substrate. Next, the shallow trench is filled with an insulation material to form a shallow trench isolation after the implantation step.

In one embodiment of the present invention, the method further includes the following steps. First, a first element region which is of a first conductive type, disposed in the epitaxial layer and adjacent to the shallow trench isolation and includes a first element is formed. Then, a second element region which is of the first conductive type, disposed in the epitaxial layer and adjacent to the shallow trench isolation and includes a second element is formed so that the isolation well region is sandwiched between the first element region and the second element region.

In another embodiment of the present invention, the first element and the second element are respectively a sensor pixel.

In another embodiment of the present invention, the substrate and a regional isolation including the extension tip together suppress a leak current which forms a hot cluster and flows from the first element region via the extension tip to the second element region.

In another embodiment of the present invention, the extension tip overlaps the substrate so that the regional isolation and the substrate together suppress a leak current which forms a hot cluster and flows from the first element region via the extension tip to the second element region.

In another embodiment of the present invention, the extension tip overlaps the substrate to substantially block the leak current.

In another embodiment of the present invention, the isolation well region and the extension tip together form a bottle shape.

In another embodiment of the present invention, the extension tip is a bottle neck of the bottle shape.

The present invention in a second aspect proposes a method for suppressing a hot cluster. First, an epitaxial layer is formed on a substrate. Second, a shallow trench is formed in the epitaxial layer. Then, an implantation step is carried to form an isolation well region in the epitaxial layer to surround the shallow trench. The isolation well region has an extension tip extending toward the substrate, and the isolation well region and the substrate are of a first conductive type. Next, the shallow trench is filled with an insulation material to form a shallow trench isolation after the implantation step. Afterwards, a first element region which is of a second conductive type different from the first conductive type, adjacent to the shallow trench isolation and includes a first element is formed in the epitaxial layer. Later, a second element region which is of the second conductive type, adjacent to the shallow trench isolation and includes a second element is formed in the epitaxial layer so that the isolation well region is sandwiched between the first element region and the second element region. The extension tip and the substrate together suppresses a leak current which forms a hot cluster caused by the first element region and flows from the first element region via the extension tip to the second element region.

In one embodiment of the present invention, the first element and the second element are respectively a CMOS image sensor (CIS).

In another embodiment of the present invention, the extension tip substantially overlaps the substrate so that the isolation well region and the substrate together form an electrical segregation to suppress a dark current caused by the leak current.

In another embodiment of the present invention, the isolation well region and the extension tip together form a bottle shape and the extension tip is a bottle neck of the bottle shape.

In another embodiment of the present invention, the depth of the extension tip is not less than that of the shallow trench.

The present invention in a third aspect proposes a semiconductor structure for suppressing a hot cluster. The semiconductor structure includes an epitaxial layer, a shallow trench isolation, an isolation well region, a first element region and a second element region. The epitaxial layer is disposed on a substrate. The shallow trench isolation is disposed in the epitaxial layer. The isolation well region is disposed in the epitaxial layer and surrounds the shallow trench. The isolation well region has an extension tip extending toward the substrate, and the isolation well region and the substrate are of a first conductive type. The first element region which is of a second conductive type different from the first conductive type, adjacent to the shallow trench isolation and includes a first element is disposed in the epitaxial layer. The second element region which is of the second conductive type, adjacent to the shallow trench isolation and includes a second element is disposed in the epitaxial layer so that the isolation well region is sandwiched between the first element region and the second element region. The substrate and a regional isolation including the extension tip together suppresses a leak current which forms a hot cluster including the first element region and the second element region and flows from the first element region via the extension tip to the second element region.

In one embodiment of the present invention, the first element and the second element are respectively a sensor pixel.

In one embodiment of the present invention, the extension tip substantially overlaps the substrate so that the regional isolation and the substrate together suppress a dark current caused by the leak current.

In one embodiment of the present invention, the isolation well region and the extension tip together form a bottle shape and the extension tip is a bottle neck of the bottle shape.

Unlike the current process, the embodiment of the present invention constructs the shallow trench isolation in the epitaxial layer before the implantation step that forms the isolation well region in the epitaxial layer. In such a way, the isolation well region may go deeper in the epitaxial layer and serve as a better isolation structure. However, the deeper isolation well region is not necessarily in direct contact with the substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1A to 1B illustrate that a hot pixel damages neighboring pixels to form multiple bad pixels and a hot cluster and the hot cluster cannot be corrected conventionally.

FIG. 2 to FIG. 5 illustrate the steps to form a semiconductor for suppressing the formation a hot cluster of the present invention.

FIG. 6 and FIG. 8 illustrate the semiconductor structure for suppressing a hot cluster of the present invention.

FIG. 7 illustrates how the present invention suppresses a hot cluster.

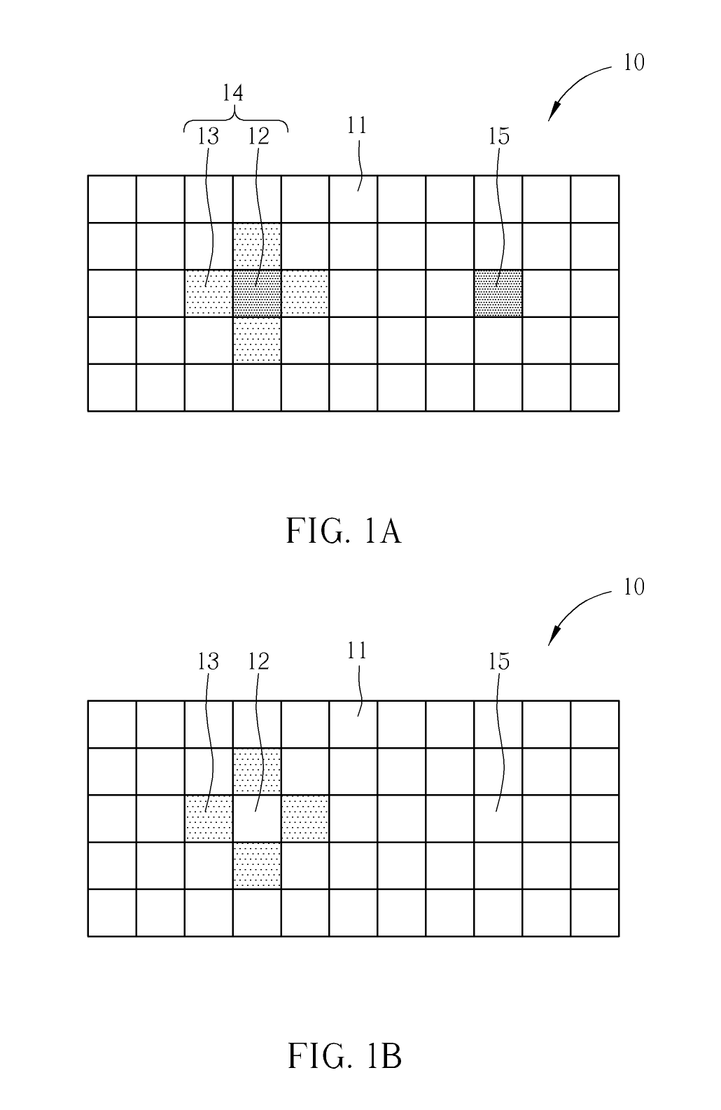

### DETAILED DESCRIPTION

The present invention provides a semiconductor structure for suppressing a hot cluster and a method to form a semiconductor for suppressing a hot cluster. This semiconductor structure and the method are used to suppress hot pixels so they are not able to collaterally damage the neighboring good pixels and not able to form a hot cluster. As a result, these hot pixels may be confined as isolated single hot pixels and can be corrected in accordance with conventional signal processing.

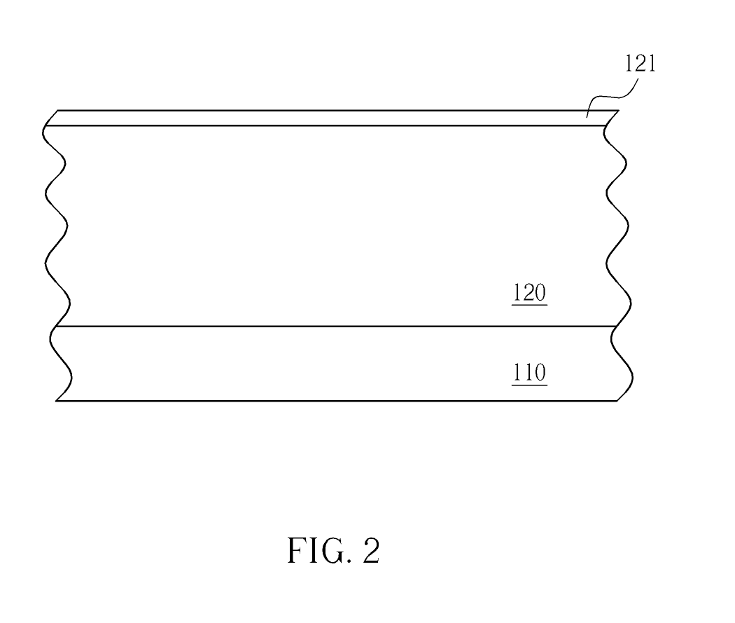

One embodiment of the present invention provides a method for forming a semiconductor, which is useful in suppressing the formation of a hot cluster in a semiconductor structure. FIG. 2 to FIG. 5 illustrate the steps to form a semiconductor for suppressing the formation of a hot cluster. First, as shown in FIG. 2, a substrate 110 is provided. Also, an epitaxial layer 120 is formed on the substrate 110 to directly contact the substrate 110. Optionally, there may be a dielectric layer 121, such as an oxide layer, disposed on the epitaxial layer 120. Further, there may be element regions serving as sensor pixels (not shown) formed in the epitaxial layer 120.

The substrate 110 may be a semiconductive material, such as Si, and has a suitable conductivity type with suitable dopant, such as a P+ substrate or an N+ substrate, and in this embodiment the substrate 110 is a P+ substrate as an example. The epitaxial layer 120 may also be a semiconductive material, such as Si and is formed on the substrate 110 conventionally.

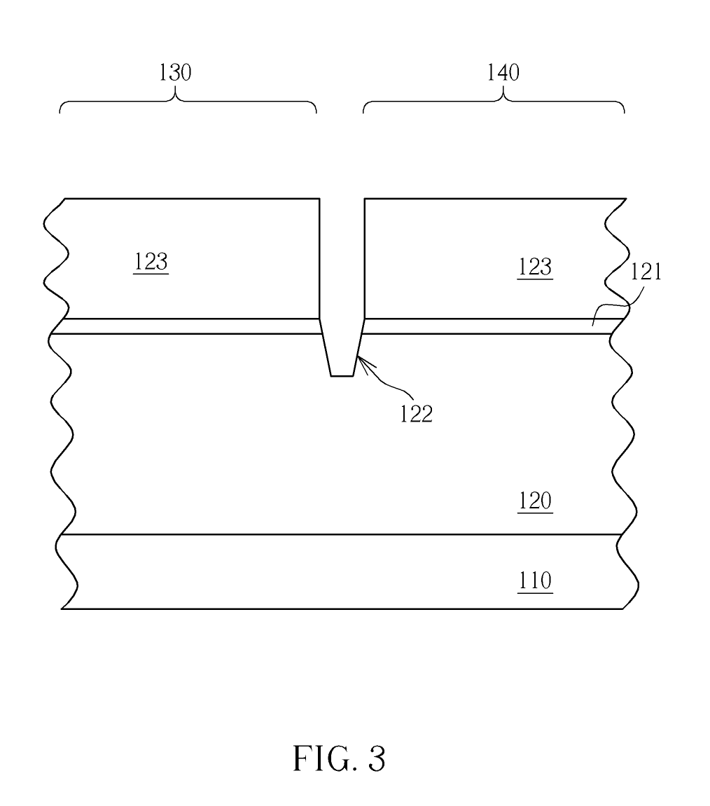

Second, as shown in FIG. 3, a shallow trench 122 is formed in the epitaxial layer 120. The shallow trench 122 will serve as a border of neighboring element regions 130 and 140. The following steps may be a possible way to form the needed shallow trench 122. First, a mask 123 is formed on the epitaxial layer 120 to define the shallow trench 122. Second, the mask 123 is used in an etching step to etch the dielectric layer 121 and the epitaxial layer 120 to form the shallow trench 122.

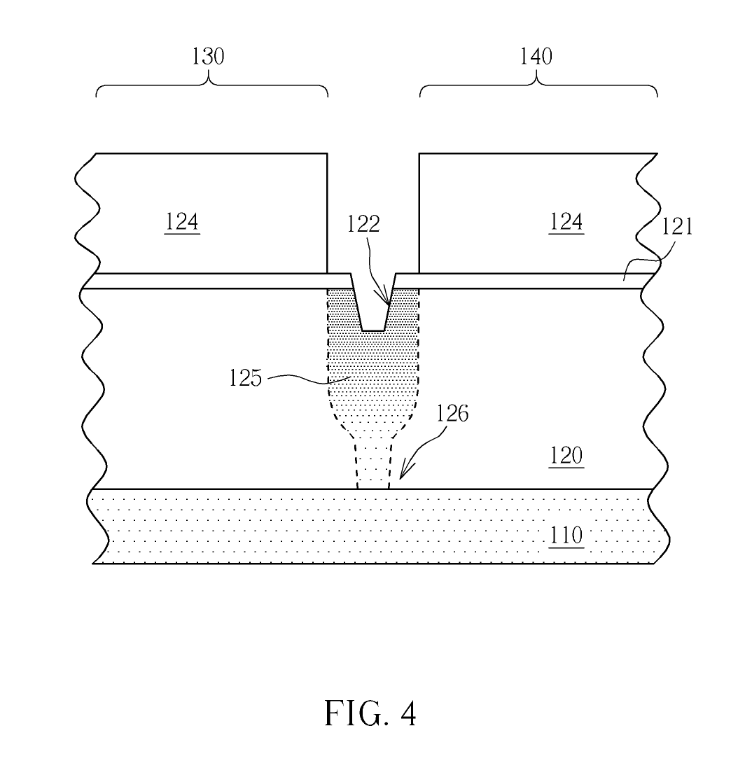

Then, a doped region 125, i.e. an isolation well region, around the shallow trench 122 is formed, as shown in FIG. 4, to isolate the neighboring element regions 130/140 and suppress a possible leak current which causes the neighboring good pixels become a hot cluster. The doped region may be formed as follows. First, please refer to FIG. 4, a process mask 124 is formed on the epitaxial layer 120. The process mask 124 may be a photoresist to define the region in the epitaxial layer 120 to be implanted. In particular, the process mask 124 may be slightly wider than the shallow trench 122 as illustrated.

Next, an implantation step is carried out. The implantation step is used to form an isolation well region 125 in the epitaxial layer 120. The isolation well region 125 is constructed to surround the shallow trench 122. The empty shallow trench 122 helps the dopant go deeper in the epitaxial layer 120 to enable a deeper and narrower doped profile, i.e. an extension tip 126.

In particular, the implantation step is well adjusted, namely optimized the implant energy and dosage, so that the isolation well region 125 develops an extension tip 126 which extends toward the substrate 110 in the presence of the shallow trench 122. The implantation step may include multiple implant stages. The extension tip 126 of the isolation well region 125 may be narrower than the isolation well region 125 itself. The extension tip 126 in the epitaxial layer 120 serves as the doped region to suppress a possible leak current.

The isolation well region 125 has the same conductivity type as the substrate 110. For example, the dopant concentration in the isolation well region 125 may be around 10¹³/cm³. It is possible that the dopant concentration in the extension tip 126 is less than that in the isolation well region 125 and a gradient concentration profile form the isolation well region 125 to the extension tip 126. For example, the dopant concentration in the extension tip 126 may be around 10¹²/cm³.

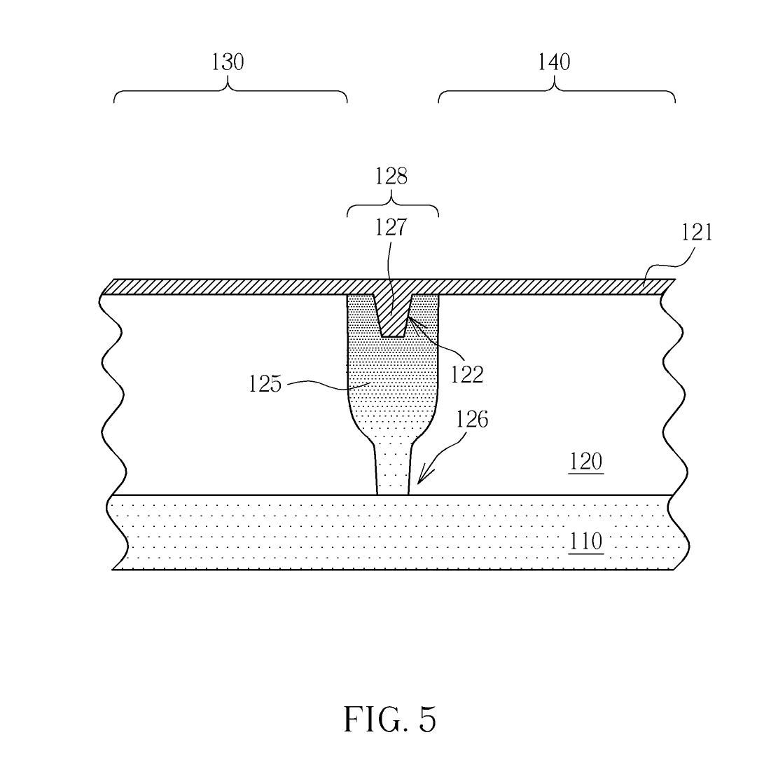

Next, as shown in FIG. 5, the shallow trench 122 is filled with an insulation material to form a shallow trench isolation 127 after the implantation step is carried out. The regional isolation 128 is formed by the shallow trench isolation 127, the isolation well region 125 and extension tip 126 together to isolate the neighboring element regions 130/140. For example, an isolation material, such as silicon oxide, is used to fill the previously formed trenches 122 to obtain the needed shallow trench isolations 127 and a planarization (CMP) is carried out to remove the excess isolation material. Moreover, the process mask 124 is removed. One feature of the method of the present embodiment resides in that these procedures are compatible with the current process.

Due to the shallow trench 122, the extension tip 126 can be formed deeper inside the epitaxy layer 120. The extension tip 126 may be deep enough to be close to the substrate 110.

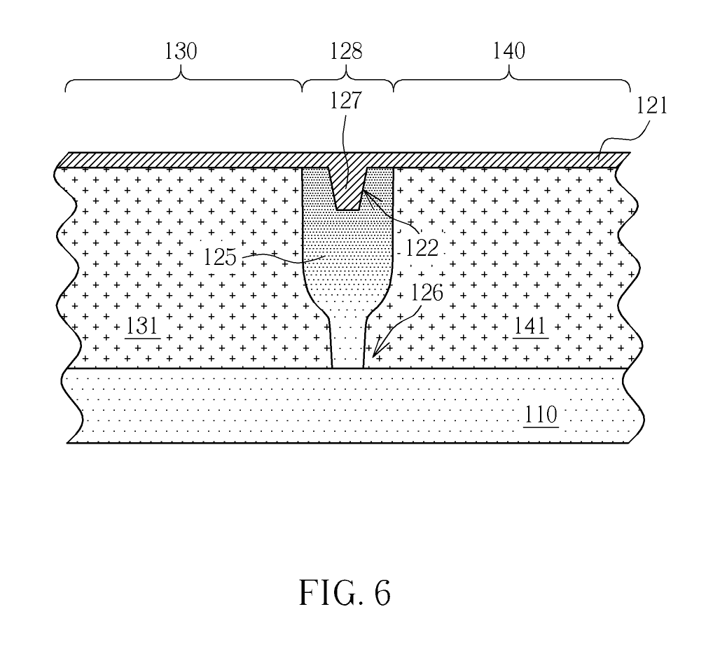

Since the semiconductor structure 110 is capable of suppressing a hot cluster, sensor pixels (not shown) respectively in the neighboring element regions 130/140 can be well-isolated. The sensor pixels are formed in the element regions, such as 130 and 140, in the semiconductor structure 110. Optionally, the steps for forming the sensor pixels may be carried out before the extension tip 126 is constructed. Alternatively, the steps for forming the sensor pixels may be carried out after the extension tip 126 is constructed as shown in FIG. 6. The sensor pixels 131 and 141 are formed respectively in the element regions 130 and 140. The sensor pixel structure is well-known and would not be described and shown here for brevity.

Preferably, the extension tip 126 overlaps the substrate 110 so that the isolation well region 125 and the substrate 110 together form an electrical segregation to electrically segregate the first element region 130 and the second element region 140.

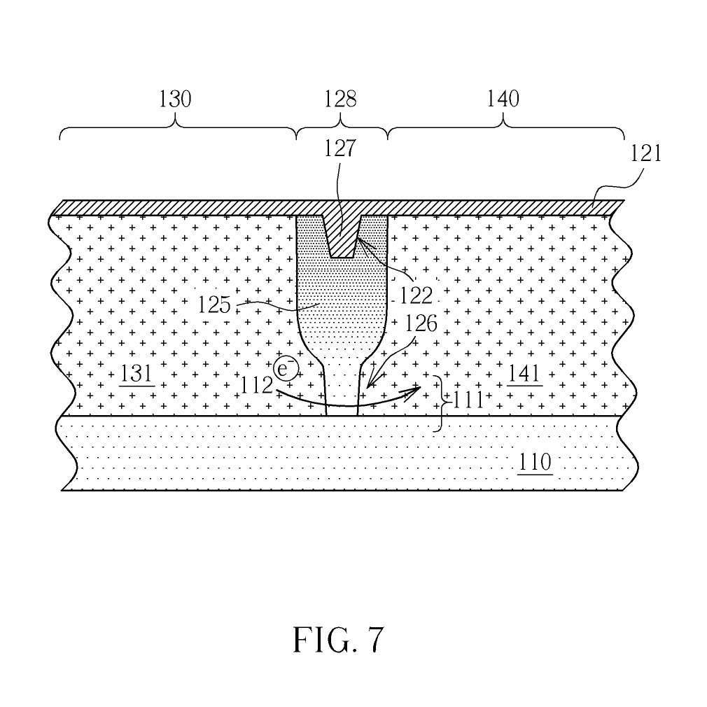

As shown in FIG. 7, if there is a leak current 112 due to a hot pixel 131, such as coming from the first element region 130, the leak current 112 would have a tendency to travel from the first element region 130 to the second element region 140, but would be blocked by the regional isolation 128. Since the leak current 112 is suppressed by the entire regional isolation 128, a hot pixel, for example the hot pixel 131 has little chance to form a hot cluster along with the neighboring pixel 141.

In a preferred embodiment, the isolation well region 125 and the extension tip 126 together forma bottle shape. For example, the extension tip 126 is a bottle neck of the bottle shape. In another preferred embodiment, the extension tip 126 overlaps the substrate 110 to substantially, or further to completely block the leak current 112. It should be noted that even though the extension tip 126 does not necessarily overlap the substrate 110, the regional isolation 128 can still substantially block the undesirable leak current 112.

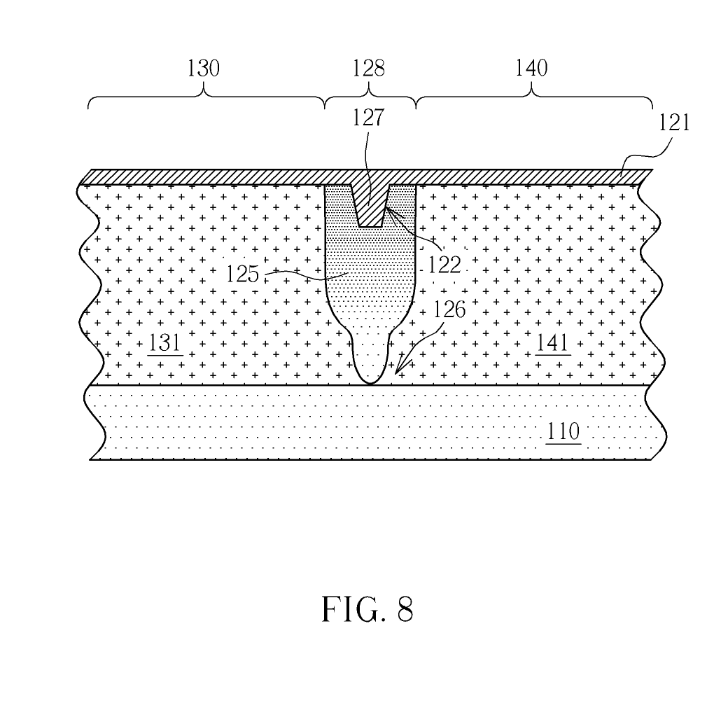

FIG. 8 illustrates an example of the semiconductor structure 100 of the present invention. As shown in FIG. 8, the semiconductor structure 100 includes a substrate 110, an epitaxial layer 120, a regional isolation 128, a first element region 130 and a second element region 140. The substrate 110 may be a semiconductive material, such as Si, and has a suitable conductivity type with suitable dopant, such as a P+ substrate or an N+ substrate, preferably a P+ substrate. The epitaxial layer 120 may also be a semiconductive material, such as Si.

The regional isolation 128 includes the isolation well region 125 and the shallow trench isolation 127, and is disposed in the epitaxial layer 120. Functionally speaking, the regional isolation 128 serves as a border of the first element region 130 and a second element region 140 which are adjacent to each other. Structurally speaking, the shallow trench isolation 128 is a shallow trench 122 which is filled with an insulation material 127.

The isolation well region 125 is also disposed in the epitaxial layer 120 and surrounds the shallow trench isolation 128. The isolation well region 125 is a doped region which has suitable dopant similar with that of the substrate 110, such as a P type dopant or an N type dopant, and a P type dopant in the embodiment. One feature of the semiconductor structure 100 of the present embodiment resides in that the isolation well region 125 further has an extension tip 126 extending toward the substrate 110.

In a preferred embodiment, the isolation well region 125 and the extension tip 126 together form a bottle shape. For example, the extension tip 126 is a bottle neck of the bottle shape. In one embodiment as shown in FIG. 8, the extension tip 126 is as close to the substrate 110 as possible. In another embodiment as shown in FIG. 6, the extension tip 126 overlaps the substrate 110.

A first element region 130 and a second element region 140 are respectively disposed in the epitaxial layer 120 and they both are adjacent to the shallow trench isolation 128.

The first element region 130 includes a first sensor pixel 131. Similarly, the second element region 140 includes a second sensor pixel 141, i.e. a CMOS image sensor (CIS) as well. The structure of the sensor pixels is well-known and would not be described here for brevity.

The regional isolation 128 and the substrate 110 together form a potential barrier of electrons generated by the sensor pixels.

Preferably, the extension tip 126 overlaps the substrate 110 so that the shallow trench isolation 127, isolation well region 125 and the substrate 110 together form an electrical segregation to electrically segregate the first element region 130 and the second element region 140.

When the extension tip 126 is present, as shown in FIG. 7, a possible leak current 112 can hardly travel from the first element region 130 to the second element region 140 because the first element region 130 and the second element region 140 in the structure are electrically segregated from each other and blocked by the regional isolation 128. Since the leak current 112 is suppressed, the semiconductor structure 100 suppresses a leak current form hot pixels so hot pixels are not able to collaterally damage the neighboring good pixels and not able to form a hot cluster. As a result, these hot pixels may be confined as isolated single hot pixels and can be corrected in accordance with conventional signal processing.

Those skilled in the art will readily observe that numerous modifications and alterations of the device and method may be made while retaining the teachings of the invention. Accordingly, the above disclosure should be construed as limited only by the metes and bounds of the appended claims.

1. A method for forming a semiconductor, comprising:
forming an epitaxial layer on a substrate;
forming a shallow trench in said epitaxial layer;
performing an implantation step to form an isolation well region in said epitaxial layer to surround said shallow trench after forming the shallow trench, wherein said isolation well region has an extension tip extending toward said substrate; and
filling said shallow trench with an insulation material to form a shallow trench isolation after performing said implantation step.

2. The method for forming a semiconductor of claim 1, further comprising:
forming a first element region which is of a first conductive type, disposed in said epitaxial layer and adjacent to said shallow trench isolation and comprises a first element; and
forming a second element region which is of said first conductive type, disposed in said epitaxial layer and adjacent to said shallow trench isolation and comprises a second element so that said isolation well region is sandwiched between said first element region and said second element region.

3. The method for forming a semiconductor of claim 1, wherein said first element and said second element are respectively a sensor pixel.

4. The method for forming a semiconductor of claim 1, wherein said substrate and a regional isolation comprising said extension tip together suppress a leak current which forms a hot cluster and flows from said first element region via said extension tip to said second element region.

5. The method for forming a semiconductor of claim 1, wherein said extension tip overlaps said substrate so that a regional isolation and said substrate together suppress a leak current which forms a hot cluster and flows from said first element region via said extension tip to said second element region.

6. The method for forming a semiconductor of claim 5, wherein said extension tip overlaps said substrate to substantially block said leak current.

7. The method for forming a semiconductor of claim 1, wherein said isolation well region and said extension tip together form a bottle shape.

8. The method for forming a semiconductor of claim 7, wherein said extension tip is a bottle neck of said bottle shape.

9. A method for suppressing a hot cluster, comprising:
forming an epitaxial layer on a substrate;
forming a shallow trench in said epitaxial layer;
performing an implantation step to form an isolation well region in said epitaxial layer to surround said shallow trench, wherein said isolation well region has an extension tip extending toward said substrate, and said isolation well region and said substrate are of a first conductive type;
filling said shallow trench with an insulation material to form a shallow trench isolation after performing said implantation step;
forming a first element region which is of a second conductive type different from said first conductive type, disposed in said epitaxial layer and adjacent to said shallow trench isolation and comprises a first element; and
forming a second element region which is of said second conductive type, disposed in said epitaxial layer and adjacent to said shallow trench isolation and comprises a second element so that said isolation well region is sandwiched between said first element region and said second element region, wherein said extension tip and said substrate together suppresses a leak current which forms a hot cluster caused by said first element region and flows from said first element region via said extension tip to said second element region.

10. The method for forming a semiconductor of claim 9, wherein said first element and said second element are respectively a CMOS image sensor (CIS).

11. The method for forming a semiconductor of claim 10, wherein said extension tip substantially overlaps said substrate so that said isolation well region and said substrate together form an electrical segregation to suppress a dark current caused by said leak current.

12. The method for forming a semiconductor of claim 9, wherein said isolation well region and said extension tip together form a bottle shape and said extension tip is a bottle neck of said bottle shape.

13. The method for forming a semiconductor of claim 9, wherein the depth of said extension tip is not less than that of said shallow trench.

14-17. (canceled)
